(19) United States
(12) Patent Application Publication
(10) Pub. No.: US 2006/0092604 A1
(43) Pub. Date: May 4, 2006

(54) Computer reader mounting device

(76) Inventor: Bang-Heng Ting, Taipei Hsien (TW)

Correspondence Address: Bang-Heng Ting, Box 8-24, 235 Chung - Ho, Taipei, TW

(21) Appl. No.: 10/978,269

(22) Filed: Nov. 1, 2004

(51) Int. Cl. G06F 1/16; H05K 5/00

(52) U.S. Cl. 361/684

(57) ABSTRACT

A computer reader mounting device installed in one slot of a computer comprises a frame positioned in the slot of the computer; a bottom of the frame being mounted with a back plate; a bottom surface of the back plate being pivotally installed with a swingable arm; a support plate locked to a rear side of the frame to be as a cartridge; one side engagable to the joint of the read unit; a sliding block being slidable in the cartridge; a bottom of the sliding block having a teeth groove; an elastomer being connected between the hook of the frame and an ear of the sliding block; a bottom plate buckled to the bottom of the frame and the bottom of the back plate; a push rod extending from the bottom plate; and a back side of the bottom plate resisting against one end of the swingable arm.

### FIELD OF THE INVENTION

The present invention relates to computer peripherals, and particularly to a computer reader mounting device, wherein the space for receiving the reading unit is smaller than the prior art so that the cost is reduced in manufacturing and shaping. Thereby the device can be installed to a 3.5 inches slot of a computer.

### BACKGROUND OF THE INVENTION

Referring to FIG. 1, a prior art of U.S. patent Ser. No. 10/158,865 invented by the inventor of the present invention is illustrated. A data reading module 1 includes a seat 11, a frame 12, a reading unit 13, panel 14 and a cover (referring to FIG. 1). The seat 11 is installed in a slot of a computer. A front side of the seat 1 is the panel 14. A push rod 122 is installed at an outer side of the frame 12. If the push rod 122, a swingable arm (not shown) is actuated so as to push out the reading unit 13 smoothly. However in above mentioned structure, since the push rod 122 is installed at an outer side of the frame 12. The reading unit 11 occupies a larger space. As a result, the manufacturing cost is high. Thereby installation and use are inconvenient.

### SUMMARY OF THE INVENTION

Accordingly, the primary object of the present invention is to provide a computer reader mounting device, wherein the space for receiving the reading unit is smaller than the prior art so that the cost is reduced in manufacturing and shaping. Thereby the device can be installed to a 3.5 inches slot of a computer.

To achieve above objects, the present invention provides a computer reader mounting device installed in one slot of a computer which comprises a frame positioned the slot of the computer; a front side of the frame installed with a panel; a lower end of the panel installed with a hook; a bottom of the frame being mounted with a back plate; a bottom surface of the back plate being pivotally installed with a swingable arm; a support plate locked to a rear side of the frame so that the support plate being locked to the frame to be as a cartridge; one side engagable to the joint of the read unit; a sliding block being slidable in the cartridge; a bottom of the sliding block having a teeth groove engageable to the oil pressure gear of the support plate; an elastomer being connected between the hook of the frame and an ear of the sliding block; a bottom plate buckled to the bottom of the frame and the bottom of the back plate; a push rod extending from a front end of the bottom plate; a back side of the bottom plate resisting against one end of the swingable arm. If the push rod is pressed, the bottom plate is pushed to slide on the bottom of the back plate. The swingable arm will be actuated to eject the stopper. By the pulling force of the elastomer and the damping force of the oil pressure gear, the read unit can be pushed out successfully.

The various objects and advantages of the present invention will be more readily understood from the following detailed description when read in conjunction with the appended drawing.

### BRIEF DESCRIPTION OF THE DRAWINGS

FIG. 1 shows an internal structure of a prior art.

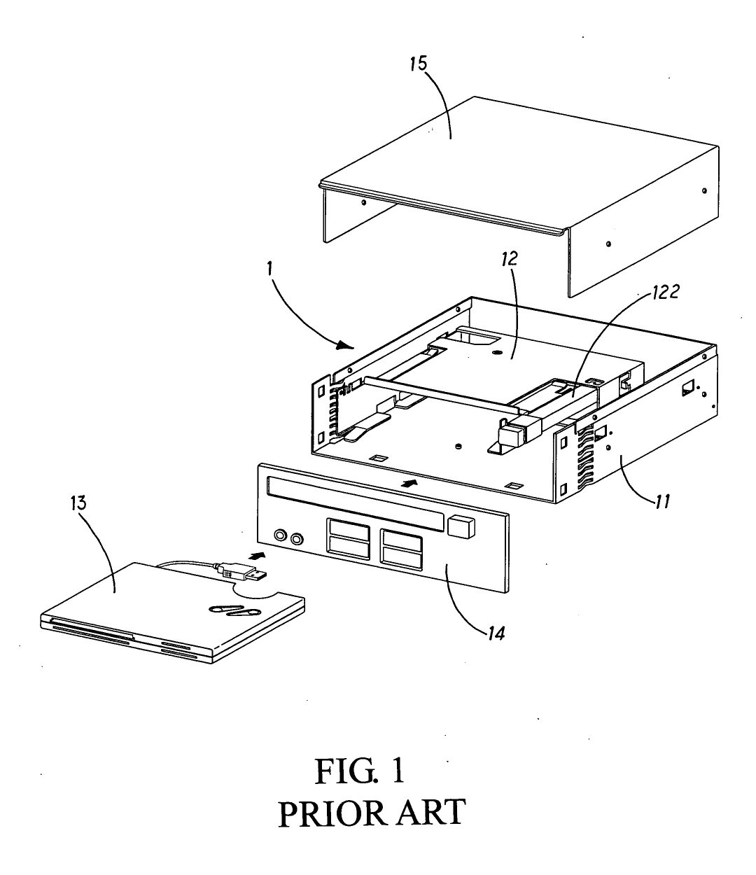

FIG. 2 shows the use of the present invention.

FIG. 3 is a schematic view showing the insertion of the computer reader mounting device to the read unit.

FIG. 4 is an exploded perspective view of the main components of the computer reader mounting device of the present invention.

FIG. 5 shows the structure of the frame and the support plate of the computer reader mounting device of the present invention.

FIG. 5-1 is a structure showing the assembly of the frame and the support plate of the computer reader mounting device of the present invention.

FIG. 6 is a structural schematic view showing that the read unit is connected to the computer reader mounting device.

FIG. 7 is a schematic view showing the pushing rod being pushed to actuate the swingable arm to move the read unit out of the computer reader mounting device.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

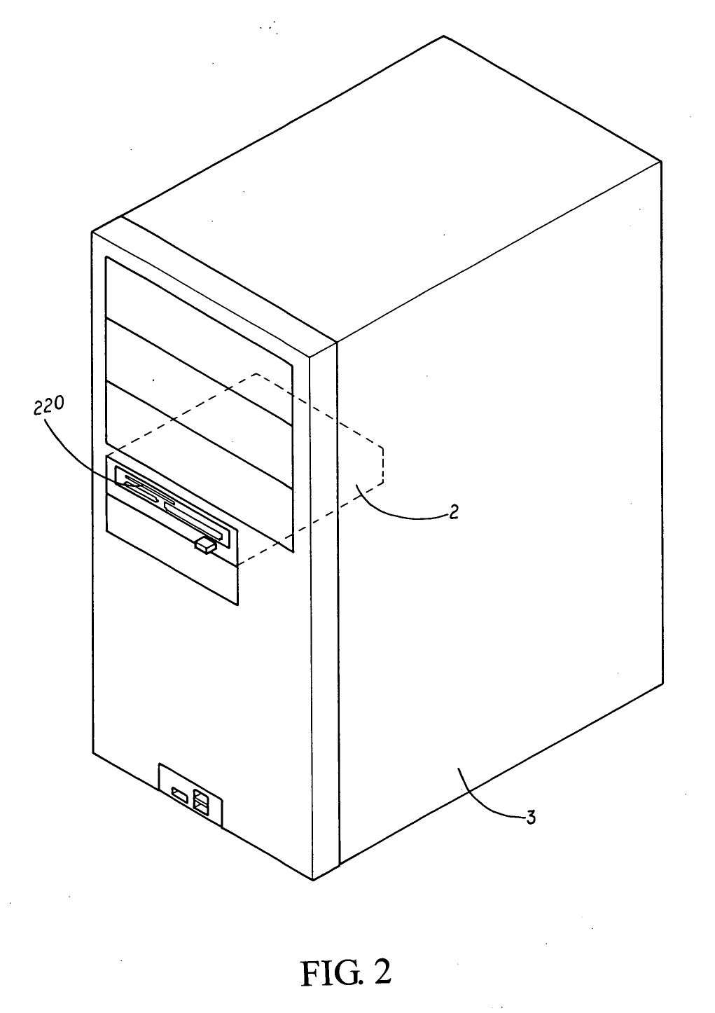

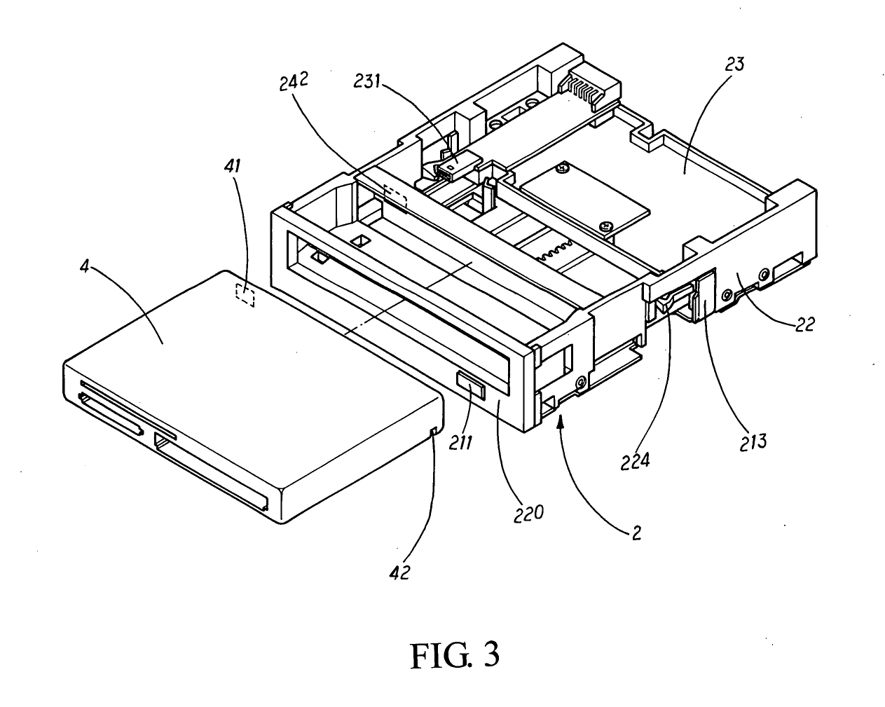

Referring to FIGS. 2 and 3, a computer reader mounting device of the present invention is illustrated. The computer reader mounting device 2 is installed in one slot of a computer (for example, a 3.5 inch slot as illustrated in the drawing). The computer reader mounting device 2 is connected to a joint 41 of a read unit 4 so as to transfer data bidirectionally with the computer 3.

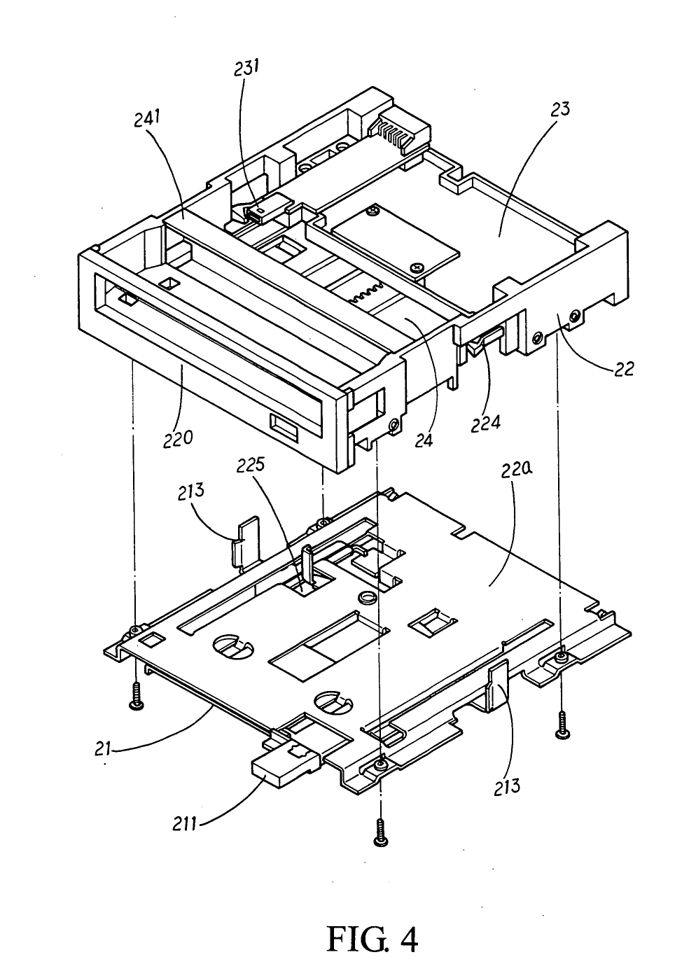

Referring to FIGS. 4 to 6, the computer reader mounting device 2 has the following elements.

A frame 22 is positioned the slot of the computer 3. A front side of the frame 22 is installed with a panel 220. A lower end of the panel 220 is installed with a hook 221. A bottom of the frame 22 is mounted with a back plate 22a. A bottom surface of the back plate 22a is pivotally installed with a swingable arm 222. One end of the swingable arm is able to protrude out of a through hole 225 of the back plate 221 and a through hole 223 of the frame 22 and a through hole 240 of the sliding block 24 to protrude out.

A support plate 23 is locked to a rear side of the frame 22 so that the support plate 23 is locked to the frame 22 to be as a cartridge. One side is engagable to the joint 41 of the read unit 4. An oil pressure gear 232 is firmly secured to a bottom of the support plate 23.

A sliding block 24 is slidable in the cartridge formed by locking the support plate 23 to the frame 22. A front end of the sliding block 24 has a stopper 241 and a via hole 242. A bottom of the sliding block 24 has a teeth groove 243 engageable to the oil pressure gear 232 of the support plate 23. A hooked ear 244 extends from a rear bottom of the sliding block 24. An elastomer 245 is connected between the hook 221 of the frame 22 and the ear 244 of the sliding block 24.

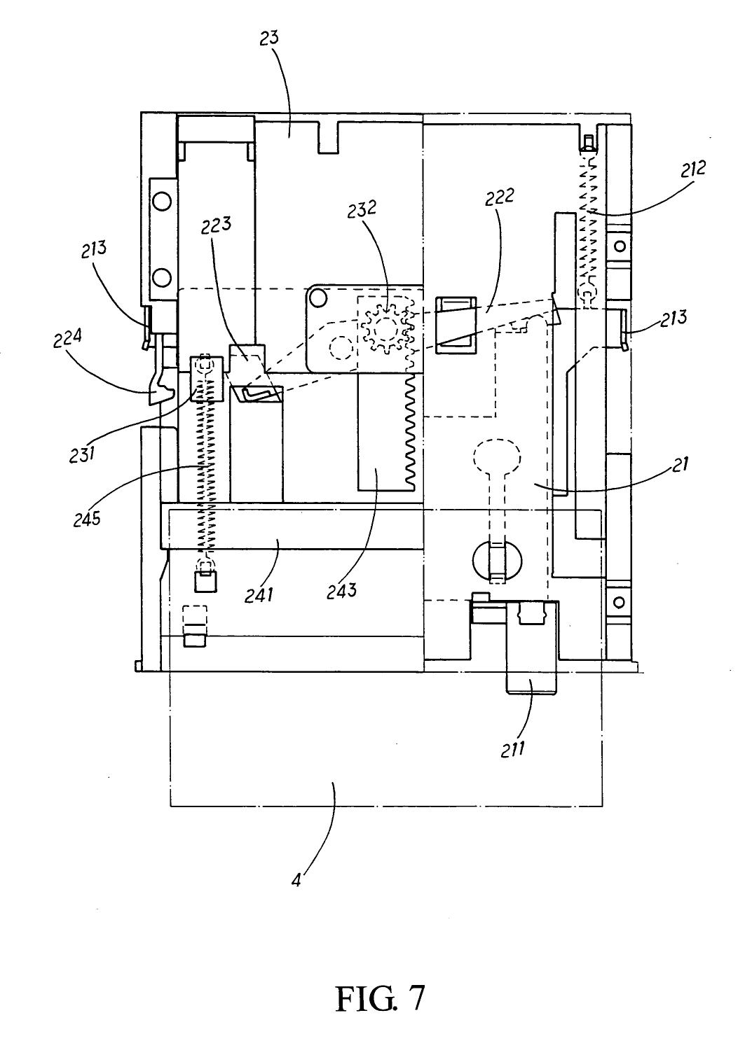

A bottom plate 21 is buckled to the bottom of the frame 22 and the bottom of the back plate 22a. A push rod 221 extends from a front end of the bottom plate 21. A backside of the bottom plate 21 resists against one end of the swingable arm 222 at the bottom of the back plate 22a of the frame 22. Elastic units 212 are installed between the rear end of the bottom plate 21 and the back plate 2a at the bottom of the frame 22. If the push rod 211 is pressed, the bottom plate 21 is pushed to slide on the bottom of the back plate 22a. Furthermore, the swingable arm 222 will be actuated to eject the stopper 241. By the pulling force 245 of the elastomer and the damping force of the oil pressure gear, the read unit 4 can be pushed out successfully (referring to FIG. 7).

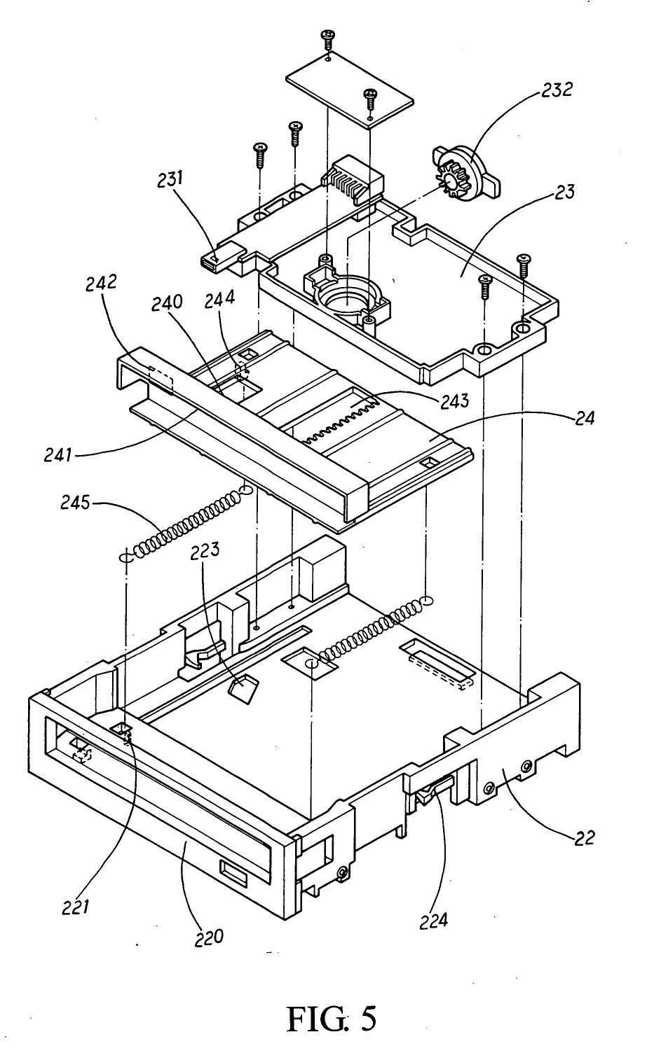

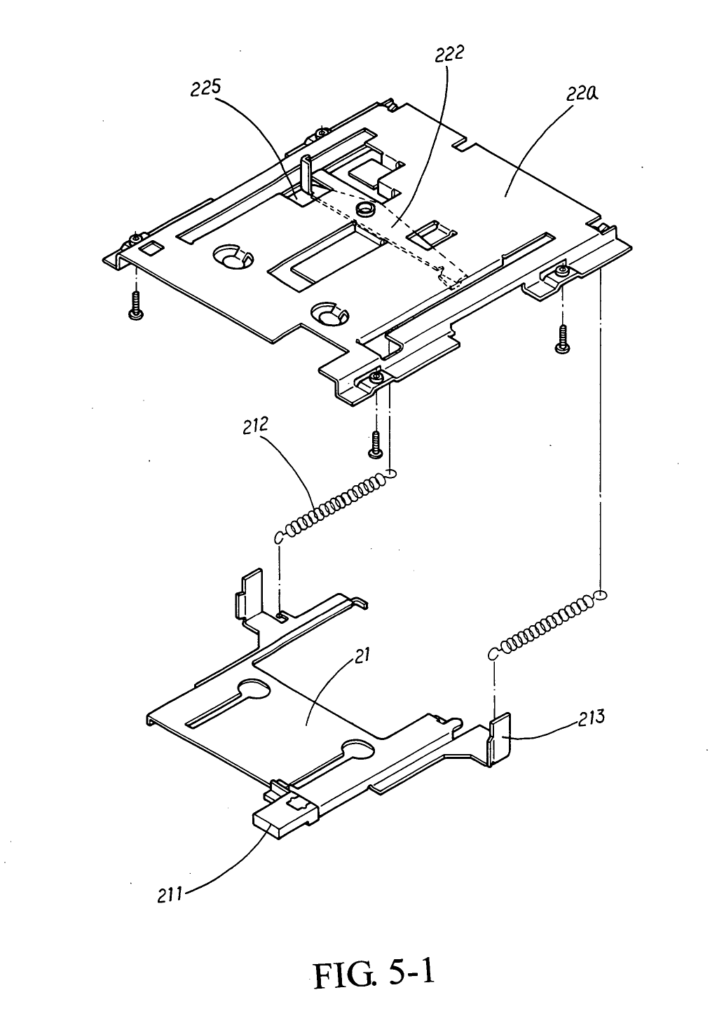

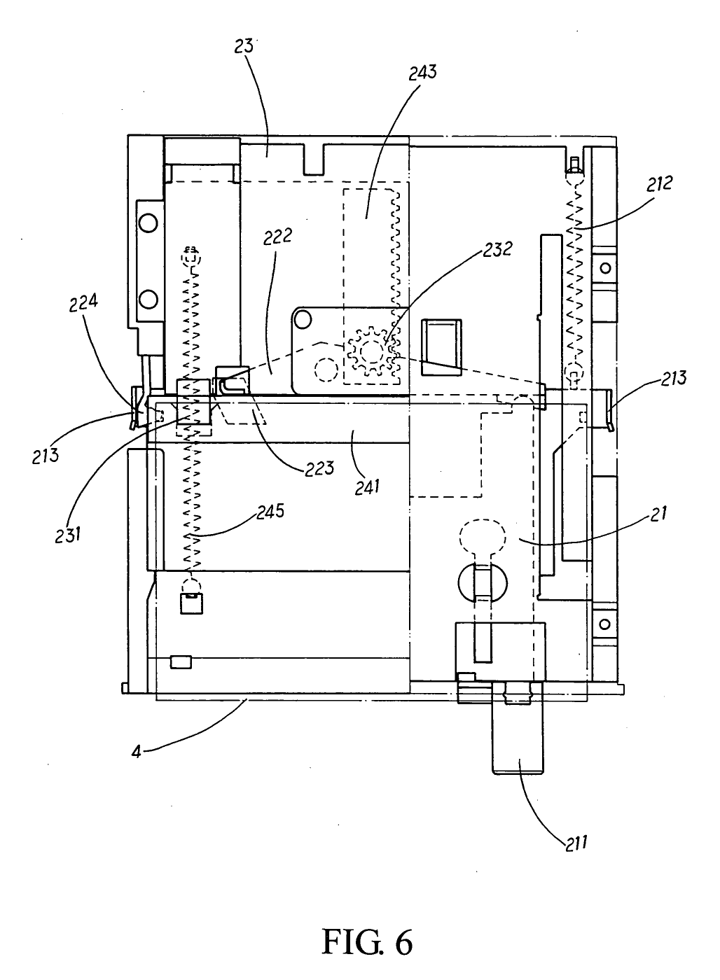

Referring to FIGS. 5 to 7, an elastic buckle 224 is formed on an outer wall of the frame 22. The bottom plate 21 has a buckling end 213 corresponding to the elastic buckle 224 of the frame 22. The bottom plate 21 is buckled to a bottom of the back plate 22a of the frame 22. When the read unit 4 is pushed continuously to pivotally rotate the swingable arm 222 so that one end of the swingable arm 222 will push the bottom plate 21 outwards, the buckling end 213 of the bottom plate 21 is exactly enforced into the concave portions 42 at two sides of the read unit. 4 to be positioned therein (referring to FIG. 6). Moreover, when the push rod 211 is pressed to move the bottom plate 21 to move backwards so that the buckling end 213 of the bottom plate 21 separates from the elastic buckle 224 (referring to FIG. 7), the elastic buckle 224 will move outwards and the engagement of the concave portions 42 so that another end of the swingable arm 222 ejects the stopper 241 and thus the read unit 4 is pushed out.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A computer reader mounting device installed in one slot of a computer; the computer reader mounting device being connected to a joint of a read unit so as to transfer data bidirectionally with the computer; the computer reader mounting device comprising:
a frame positioned in the slot of the computer; a front side of the frame installed with a panel; a lower end of the panel installed with a hook; a bottom of the frame being mounted with a back plate; a bottom surface of the back plate being pivotally installed with a swingable arm; one end of the swingable arm being able to protrude out of a through hole of the back plate and a through hole of the frame and a through hole of the sliding block to protrude out;
a support plate locked to a rear side of the frame so that the support plate being locked to the frame to be as a cartridge; one side engagable to the joint of the read unit; an oil pressure gear being firmly secured to a bottom of the support plate;
a sliding block being slidable in the cartridge formed by locking the support plate to the frame; a front end of the sliding block having a stopper and a via hole; a bottom of the sliding block having a teeth groove engageable to the oil pressure gear of the support plate; an hooked ear extending from a rear bottom of the sliding block; an elastomer being connected between the hook of the frame and the ear of the sliding block;
a bottom plate buckled to the bottom of the frame and the bottom of the back plate; a push rod extending from a front end of the bottom plate; a back side of the bottom plate resisting against one end of the swingable arm at the bottom of the back plate of the frame; if the push rod being pressed, the bottom plate being pushed to slide on the bottom of the back plate; the swingable arm will be actuated to eject the stopper; by the pulling force of the elastomer and the damping force of the oil pressure gear, the read unit can be pushed out successfully.

2. The computer reader mounting device as claimed in claim 1, wherein the computer slot is a 3.5 inches slot.

3. The computer reader mounting device as claimed in claim 1, wherein an elastic buckle is formed on an outer wall of the frame; the bottom plate has a buckling end corresponding to the elastic buckle of the frame; the bottom plate is buckled to a bottom of the back plate of the frame; when the read unit is pushed continuously to pivotal rotate the swingable arm so that one end of the swingable arm will push the bottom plate outwards, the buckling end of the bottom plate is exactly enforced into the concave portions at two sides of the read unit to be positioned therein; when the push rod is pressed to move the bottom plate to move backwards so that the buckling end of the bottom plate separates from the elastic buckle, the elastic buckle will move outwards and the engagement of the concave portions so that another end of the swingable arm ejects the stopper and thus the read unit is pushed out.

4. The computer reader mounting device as claimed in claim 1, wherein elastic units being installed between the rear end of the bottom plate and the back plate at the bottom of the frame.
